(19) United States
(12) Patent Application Publication
(10) Pub. No.: US 2006/0039214 A1
(43) Pub. Date: Feb. 23, 2006

(54) Driving circuit, driving method of electro-optical device, electro-optical device, and electronic apparatus

(75) Inventor: Yasuji Yamasaki, Chitose-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/171,209

(22) Filed: Jul. 1, 2005

(30) Foreign Application Priority Data
Aug. 20, 2004 (JP) 2004-241000

(51) Int. Cl. G11C 7/00

(52) U.S. Cl. 365/203

(57) ABSTRACT

A driving circuit of an electro-optical device having a plurality of scanning lines, a plurality of data lines, and a plurality of pixel electrodes electrically connected to the scanning lines and the data lines, respectively, in an image display region on a substrate, the driving circuit includes a shift register circuit which sequentially outputs transfer signals from respective stages, a first arithmetic logic circuit which outputs the sequentially output transfer signals and selection signals for precharge input from a first input terminal to a first path by a logical operation, a second arithmetic logic circuit which generates sampling signals by a logical operation between the transfer signals input from the first path and enable signals input from a second input terminal, and which outputs the generated sampling signals and the selection signals for precharge input from the first path to a second path, and a sampling circuit including a plurality of sampling switches which sample precharge signals, which are supplied via an image signal line and have precharge potentials, according to the selection signals for precharge supplied via the second path, and supplies the sampled signals to the data lines, respectively, and sample image signals, which are supplied via the image signal line and have display potentials, according to the sampling signals supplied via the second path, and which supplies the sampled signals to the data lines, respectively.

### BACKGROUND OF THE INVENTION

1. Technical Field

The invention relates to a driving circuit and to a driving method for driving an electro-optical device such as a liquid crystal device, to an electro-optical device including the driving circuit, and to an electronic apparatus such as a liquid crystal projector which has the electro-optical device provided therein.

2. Related Art

The electro-optical device driven by the driving circuit includes a plurality of data lines, a plurality of scanning lines, and pixel electrodes which are electrically connected to the data lines and the scanning lines, respectively, and are provided to every pixel portion, in an image display region on a substrate.

According to Japanese Unexamined Patent Application Publication Nos. 10-282938, 2001-356746, 2002-297105, 2002-297106, and 11-65536, during the time of driving the electro-optical device, a sampling signal is generated in the driving circuit by performing a waveform shaping depending on an enable signal with respect to transfer signals sequentially output from a shift register, respectively, and the generated sampling signal is supplied to a sampling circuit. The sampling circuit includes a plurality of sampling switches corresponding to the plurality of data lines and an image signal is supplied to corresponding data line through the sampling switch turned on according to the sampling signal.

Each of the pixel electrodes becomes a selected state according to a scanning signal supplied via each of the scanning lines, and an image signal supplied to the corresponding data line is written into a display element such as a liquid crystal element by the pixel electrode. A technology for reducing ghosting in a display image by performing a sampling with respect to each of the data lines or pixel portion corresponding to the data line prior to the writing of the image signal is disclosed in the above mentioned Japanese Unexamined Patent Application Publications.

Further, the image signal adjusted to have the precharge potential and the display potential is supplied to the driving circuit from an external circuit. Further, a selection signal for precharge is supplied from the external circuit to the driving circuit in addition to the enable signal. Generally, the enable signal is generated in the external circuit as a relatively high-speed pulse and is supplied to the driving circuit. The driving circuit is provided with, for example, an arithmetic logic circuit which outputs the selection signal for precharge and a sampling signal generated by waveform-shaping the transfer signal output from the shift register by the enable signal to the same path.

Further, the image signal is supplied to the corresponding data line through the sampling switch turned on according to the selection signal for precharge or the sampling signal. As a result, the image signal having the precharge potential is simultaneously supplied to the plurality of data lines according to the selection signal for precharge. Hereinafter, the precharge performed in this way is referred to as a video precharge.

However, in case of performing the above-described precharge, an output timing of the sampling signal may be delayed with respect to an input timing of the enable signal in each arithmetic logic circuit. In this way, when the output timing of the sampling signal is delayed in the arithmetic logic circuit, ON and OFF of the sampling switch is delayed, such that a display irregularity is generated in addition to that the ghosting is viewed on display, thereby deteriorating the display quality.

### SUMMARY

An advantage of the invention is that it provides a driving circuit and a driving method of an electro-optical device, which is capable of performing an image display with high quality, an electro-optical device including the driving circuit, and various electronic apparatus including the electro-optical device.

According to an aspect of the invention, a driving circuit of the electro-optical device has a plurality of scanning lines, a plurality of data lines, and a plurality of pixel electrodes electrically connected to the scanning lines and the data lines, respectively, in an image display region on a substrate. The driving circuit includes a shift register circuit which sequentially outputs transfer signals from respective stages, a first arithmetic logic circuit which outputs the sequentially output transfer signals and selection signals for precharge input from a first input terminal to a first path by a logical operation, a second arithmetic logic circuit which generates sampling signals by a logical operation between the transfer signals input from the first path and enable signals input from a second input terminal and outputs the generated sampling signals and which the selection signals for precharge input from the first path to a second path, and a sampling circuit including a plurality of sampling switches which sample precharge signals, which are supplied via an image signal line and have precharge potentials, according to the selection signals for precharge supplied via the second path and supplies the sampled signals to the data lines, respectively, and sample image signals, which are supplied via the image signal line and have display potentials, according to the sampling signals supplied via the second path and supplies the sampled signals to the data lines, respectively.

According to the driving circuit of the electro-optical device of the invention, during the time of driving the electro-optical device, the shift register circuit sequentially generates the transfer signals and outputs them on the basis of the various timing signals supplied from an external circuit.

In the above-mentioned structure, it is preferable that the first and second arithmetic logic circuit are disposed corresponding to respective stages of the shift register. The first arithmetic logic circuit is supplied with the selection signals for precharge from an external circuit and the transfer signals output from the shift register circuit, via the first input terminal thereof. The first arithmetic logic circuit outputs the input transfer signals and the selection signals for precharge to the first path through the logical operation.

Further, the second arithmetic logic circuit is supplied with the enable signals from an external circuit via the second input terminal, and the transfer signals and the selection signals for precharge from the first path, via the first input terminal. The second arithmetic logic circuit generates the sampling signals through the logical operation between the transfer signals and the enable signals supplied thereto. The selection signals for precharge and the sampling signals are output to the second path from the second arithmetic logic circuit.

Therefore, according to the driving circuit of the invention, it is possible to reduce the number of logical operations using the enable signals input to the second input terminal, compared to the number of logical operations until the selection signals for precharge are output to the second path after they are input the first input terminal. Further, it is possible to shorten the signal path until the sampling signals are output to the second path after the enable signals are input the second input terminal, compared to the signal path until the selection signals for precharge are output to the second path after they are input to the first input terminal.

Further, the selection signals for precharge and the sampling signals are supplied to the sampling circuit via the second path.

The external circuit supplies the selection signals for precharge, prior to the supply of the timing signals for generating the transfer signals in the shift register circuit. At this time, the enable signals may be supplied from the external circuit with the selection signals for precharge depending on the kind of the logical operation in the first and second arithmetic logic circuits. The selection signals for precharge are output to the first path from the first arithmetic logic circuit prior to the output timing of the transfer signals. Further, the selection signals for precharge are output to the second path form the second arithmetic logic circuit prior to the output timing of the sampling signals.

Further, the precharge signals with the precharge potential are supplied to the sampling circuit via the image signal line in synchronization with the supply timing of the selection signal for precharge. In the sampling circuit, each sampling switch is turned on according to the supplied selection signal for precharge, samples the precharge signal, and supplies the sampled signal to the plurality of data lines. For example, the precharge signal is simultaneously written to the plurality of data lines, whereby the video precharge is performed.

The sampling circuit is supplied with the sampling signal, after the supply of the selection signals for precharge and the precharge signals are terminated. Further, the sampling circuit is supplied with the image signals with the display potentials via the image signal line, in synchronization with the supply timing of the timing signals for generating the transfer signals in the resistor circuit and the enable signals from the external circuit.

In the sampling circuit, each sampling switch is turned on in accordance with the supplied sampling signal, samples the image signal, and supplies the sampled signal to the plurality of data lines, respectively. In each of the pixel portions, the image electrode is supplied with the image signal from the data line via, for example, a thin film transistor (hereinafter, refer to as TFT) for switching the pixel formed in the pixel portion, according to the scanning signal via the scanning line.

Here, the sampling signal is generated at the timing based on the enable signal in the second arithmetic logic circuit and the generated sampling signal is output to the second path. The enable signal is supplied from the external circuit, with the number according to the transfer signal output from each stage of the shift register and as a signal synchronized with the output timing of the transfer signal. Therefore, as the number of the stage of the shift register circuit increases, the enable signal is supplied from the external circuit as a high-speed pulse.

According to the driving circuit of the invention, as described above, the number of logical operations which use the enable signals is reduced, and the signal path, until the sampling signals are output to the second path after the enable signals are input to the second input terminal, is shortened, such that it is possible to prevent the output timing of the sampling signals to the second path from being delayed with respect to the input timing of the enable signals to the second input terminal.

Therefore, it is possible to enlarge the margin of the ghosting generation in the display image caused by the delay of the on and off of the sampling switches. Specifically, according to the driving circuit of the invention, it is possible to prevent the ghosting in the display image from being generated and to prevent display irregularity caused by the delay of the output timing of the sampling signals from being generated. Thus, according to the driving circuit of the invention, it is possible to realize the image display with high quality in the electro-optical device.

Further, in the driving circuit according to the invention, the first and second paths may be provided with a buffer, an inverter or the like.

In the above-described structure, the first and second arithmetic logic circuits are preferably constructed so that the number of logical operations operated from the second input terminal to the second path is smaller than the number of logical operations operated from the first input terminal to the second path.

According to the above-described structure, it is possible to shorten the signal path until the sampling signals are output to the second path after the enable signals are input the second input terminal, compared to the signal path until the selection signals for precharge are output to the second path after they are input to the first input terminal. Therefore, it is possible to prevent the output timing of the sampling signals to the second path from being delayed with respect to the input timing of the enable signals to the second input terminal.

In the above-described structure, it is preferable that the second input terminal be disposed closer to the sampling circuit compared to the first input terminal.

According to the above-described structure, it is possible to reduce the number of logical operations using the enable signals input to the second input terminal, compared to the number of logical operations until the selection signals for precharge are output to the second path after they are input the first input terminal. Further, it is possible to shorten the signal path until the sampling signals are output to the second path after the enable signals are input the second input terminal, compared to the signal path until the selection signals for precharge are output to the second path after they are input to the first input terminal.

In the above-described structure, it is preferable that the first arithmetic logic circuit output the transfer signals and the selection signals for precharge to the first path by performing logical sums of the transfer signals and the selection signals for precharge. Further, it is preferable that the second arithmetic logic circuit generate the sampling signals by taking logical multiplications of the transfer signals and the enable signals.

According to the structure, as described above, after the selection signals for precharge are supplied, the timing signal for generating the transfer signals in the resistor circuit and the enable signals are supplied from the external circuit, such that the transfer signals and the selection signals for precharge are output to the first path from the first arithmetic logic circuit.

Further, the second arithmetic logic circuit is supplied with the enable signals via the second input terminal thereof such that they are overlapped with the transfer signals output to the first path and the selection signals for precharge, respectively, on the time base. Therefore, it is possible to output the sampling signals after the selection signals for precharge are output to the second path from the second arithmetic logic circuit.

According to the structure, the second input terminal is supplied with any one of plural types of enable signals.

According to the above-described structure, the plural types of enable signals are supplied from the external circuit. Therefore, it is possible to supply each of the enable signals to the second input terminal as a low speed pulse, compared to one series of enable signals.

To achieve the above-described advantage, the electro-optical device according to the invention includes the above-described driving circuit of the electro-optical device (including various aspects thereof) of the invention.

According to the electro-optical device of the invention, the electro-optical device is driven by the above-described driving circuit, such that it is possible to enhance the quality of the display image in the image display region.

To achieve the above-described advantage, the electronic apparatus of the invention includes the above-described electro-optical device of the invention.

The electronic apparatus of the invention includes the above-described electro-optical device, such that it is possible to realize a projection type display apparatus, a television, a portable telephone, an electronic organizer, a word processor, a view finder type or monitor-direct-view type video tape recorder, an workstation, a video telephone, a POS terminal, and various electronic apparatus having a touch panel, which is capable of performing an image display with high quality. Further, as the electronic apparatus of the invention, it is possible to realize, for example, an electrophoresis device such as an electronic paper, an electron-emitting device (such as Field Emission Display and Conduction Electron-Emitter Display), a DLP (Digital Light Processing) as a device using the electrophoresis device or the electron-emitting device and the like.

According to another aspect of the invention, the method of driving the electro-optical device having a plurality of scanning lines, a plurality of data lines, and a plurality of pixel electrodes electrically connected to the scanning lines and the data lines, respectively, in an image display region on a substrate, includes a first step of sequentially outputting transfer signals from respective stages, a second step of outputting the sequentially output transfer signals and selection signals for precharge input from a first input terminal to a first path by a logical operation, a third step of generating sampling signals by a logical operation between the transfer signals input from the first path and enable signals input from a second input terminal and outputting the generated sampling signal and the selection signals for precharge input from the first path to a second path, and a fourth step of sampling precharge signals, which are supplied via an image signal line and have precharge potentials, according to the selection signals for precharge supplied via the second path and supplying the sampled signals to the data lines, respectively, and sampling image signals, which are supplied via the image signal line and have display potentials, according to the sampling signals supplied via the second path and supplying the sampled signals to the data lines, respectively.

According to the above-described method, it is possible to perform the image display with high quality in the electro-optical device, like the above-described driving circuit of the invention.

### BRIEF DESCRIPTION OF THE DRAWINGS

The invention will be described with reference to the accompanying drawings, wherein like numbers reference like elements, and wherein:

FIG. 1 is a plan view showing the entire construction of a liquid crystal panel;

FIG. 2 is a cross-sectional view taken along the line II-II of FIG. 1;

FIG. 3 is a block diagram showing the entire construction of the liquid crystal device;

FIG. 4 is a block diagram showing an electrical construction of the liquid crystal panel;

FIG. 5 is a circuit diagram showing the construction of an arithmetic logic unit;

FIG. 6 is a view showing a timing chart for illustrating the operation of an electro-optical device;

FIG. 7 is a circuit diagram showing the construction of the arithmetic logic unit according to a comparative example;

FIG. 8 is a view showing the timing chart for illustrating the operation of the electro-optical device according to the comparative example;

FIG. 9 is a circuit diagram showing a construction of the arithmetic logic unit according to the modification;

FIG. 10 is a view showing the timing chart for illustrating the operation of the electro-optical device according to the modification;

FIG. 11 is a plan view showing the construction of a projector, which is an example of an electronic apparatus adopting the liquid crystal device;

FIG. 12 is a perspective view showing the construction of a personal computer which is an example of the electronic apparatus adopting the liquid crystal device; and

FIG. 13 is a perspective view showing the construction of a mobile telephone, which is an example of the electronic apparatus adopting the liquid crystal device.

### DESCRIPTION OF THE EMBODIMENTS

The operation and another advantage of the invention will be apparent from embodiments to be described below.

Hereinafter, preferred embodiments of the invention will be described with reference to the accompanying drawings. In the embodiments to be described, the electro-optical device of the invention is applied to a liquid crystal device.

<1: Entire Construction of Electro-Optical Panel>

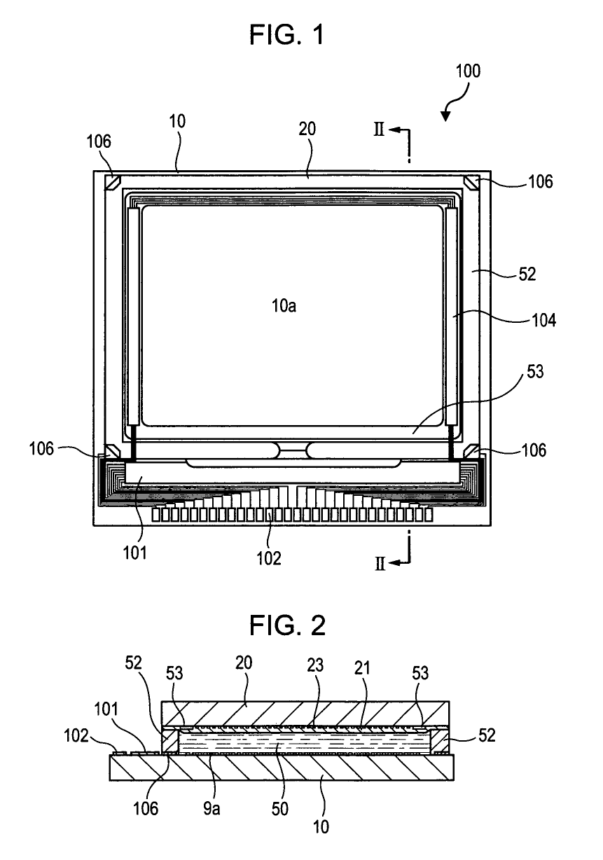

First, in a liquid crystal device which is an example of the invention, the entire construction of a liquid crystal panel as an example of an electro-optical panel will be described with reference to FIGS. 1 and 2. Here, FIG. 1 is a schematic plan view of the liquid crystal panel, in which a TFT array substrate is seen from a counter substrate together with each element formed on a TFT array substrate, and FIG. 2 is a cross-sectional view taken along the line II-II of FIG. 1. Here, a TFT active matrix driving type liquid crystal device with built-in driving circuits will be described as an example.

In FIGS. 1 and 2, the liquid crystal panel 100 according to the present embodiment is so constructed that the TFT array substrate 10 and the counter substrate 20 face each other. A liquid crystal layer 50 is interposed between the TFT array substrate 10 and the counter substrate 20, and the TFT array substrate 10 and the counter substrate 20 are adhered to each other by a sealing material 52 disposed in a sealing region at the periphery of an image display region 10a.

The sealing material 52 is made of, for example, an ultraviolet curable resin, a thermosetting resin or the like for bonding both of the substrates to each other. In the manufacturing process, the sealing material 52 is applied onto the TFT array substrate 10, and is cured by an irradiation of ultra-violet rays, a heating or the like. Further, a gap material such as glass fiber and glass beads is dispersed in the sealing material 52 to maintain the gap (a gap between the substrates) between the TFT array substrate 10 and the counter substrate 20 at a predetermined value.

A casing light-shielding film 53 of a light-shielding performance defining a casing region of an image display region 10a is disposed on the counter substrate 20 side parallel to the inner side of the sealing region where the sealing material 52 is disposed. Here, a part or all of the casing light-shielding film 53 may be disposed as a built-in light-shielding film built on the TFT array substrate 10.

In a region located at an outside the sealing region in which the sealing material 52 is disposed, among the peripheral regions of the image display region 10a, a data line driving circuit 101 and an external circuit connecting terminals 102 are disposed along one side of the TFT array substrate 10. Further, a scanning line driving circuit 104 is disposed along any one of sides adjacent to the one side so as to be covered with the casing light-shielding film 53. Furthermore, the scanning line driving circuit 104 may be disposed along two sides adjacent to the one side of the TFT array substrate 10 in which the data line driving circuit 101 and the external circuit connecting terminals 102 are disposed. In this case, the two scanning line driving circuits 104 are connected to each other by a plurality of wiring lines formed along a remaining one side of the TFT array substrate 10.

Further, up-and-down conductive material 106 which functions as an up-and-down conductive terminal between both the substrates is arranged at four corners of the counter substrate 20. On the other hand, up-and-down conductive terminals are disposed in regions of the TFT array substrate 10 that face the four corners. Therefore, it is possible to electrically connect the TFT array substrate 10 to the counter substrate 20.

In FIG. 2, on the TFT array substrate 10, an alignment film is formed above a pixel electrode 9a on which a TFT for a pixel switch or wiring lines such as scanning lines and data lines have been formed. On the other hand, on the counter substrate 20, a light-shielding film 23 in the shape of matrix or stripe is formed and an alignment film is formed at the uppermost position thereof, in addition to a counter electrode 21. Further, a liquid crystal layer 50 is composed of a liquid crystal to which one or several kinds of nematic liquid crystal is mixed, and is maintained at a predetermined alignment state between a pair of alignment films.

Further, even though it is not shown at FIGS. 1 and 2, a sampling circuit which samples an image signal on an image signal line and supplies it to the data lines to be described later is formed on the TFT array substrate 10, in addition to the data line driving circuit 101 or the scanning line driving circuit 104. In the present embodiment, a test circuit for testing a quality, defect or the like of the electro-optical device during the time of manufacturing process or shipment may be formed other than the sampling circuit.

<2: Entire Construction of Electro-Optical Device>

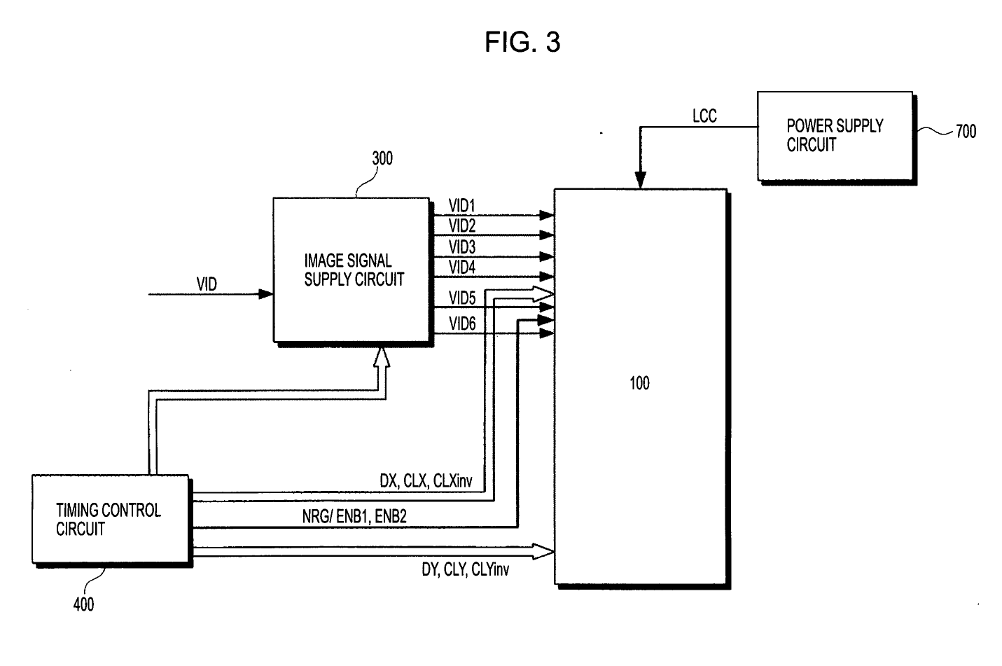

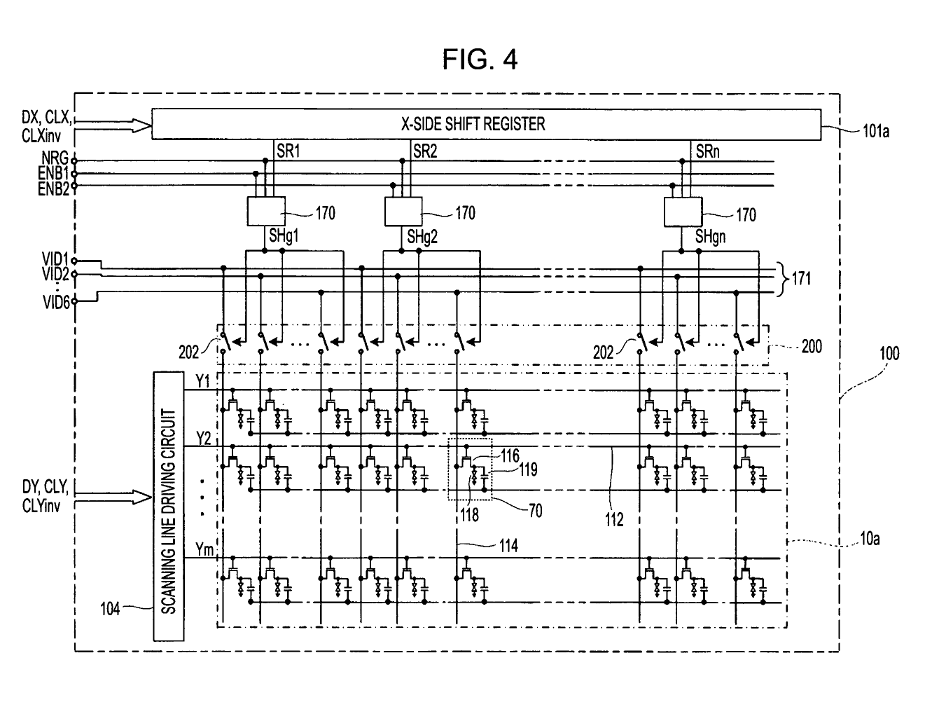

The entire construction of the electro-optical device will be described with reference to FIGS. 3 and 4. Here, FIG. 3 is a block diagram showing the entire construction of the liquid crystal device, and FIG. 4 is a block diagram showing an electrical construction of the liquid crystal panel.

As shown in FIG. 3, the liquid crystal device includes the liquid crystal panel 100, an image signal supply circuit 300, a timing control circuit 400, and a power supply circuit 700 disposed as an external circuit.

The timing control circuit 400 is constructed so as to output various timing signals to be used in each part. A dot clock, which is a clock of minimum unit and scans each pixel, is generated by a timing signal output unit which is a part of the timing control circuit 400. Based on the dot clock, a Y clock signal CLY, an inverted Y clock signal CLYinv, an X clock signal CLX, an inverted X clock signal XCLinv, a Y start pulse DY, and an X start pulse DX are generated. Further, the timing control circuit 400 generates a selection signal for precharge NRG, first and second enable signals ENB1 and ENB2 determining an output of the sampling signal to be described below.

One-system input image data VID is input to the image signal supply circuit 300 from the outside. The image signal supply circuit 300 serial-parallel converts the one-system input image data VID, and generates image signals VID1 to VID6 of N phases (in the present embodiment, six phases (N=6)). Further, in the image signal supply circuit 300, each voltage of the image signals VID1 to VID6 may be inverted into a positive polarity and a negative polarity with respect to a predetermined reference voltage, and the image signals VID1 to VID6 inverted in this way may be output.

Further, the power supply circuit 700 supplies a common power source with a predetermined common potential LCC to the counter electrode 21 shown in FIG. 2. In the present embodiment, the counter electrode 21 is formed under the counter substrate 20 so as to face a plurality of pixel electrodes 9a shown in FIG. 2.

Next, an electrical construction of the liquid crystal panel 100 will be described.

An internal driving circuit including the sampling circuit 200 is disposed in the liquid crystal panel 100 at the peripheral region of the TFT array substrate 10, in addition to the scanning line driving circuit 104 and the data line driving circuit 101 shown in FIG. 2.

In FIG. 4, the Y clock signal CLY, the inverted Y clock signal CLYinv, and the Y start pulse DY are supplied to the scanning line driving circuit 104. When the Y start pulse DY is input to the scanning line driving circuit 104, the scanning line driving circuit 104 sequentially generates and outputs scanning signals Y1, . . . , Ym at the timing based on the Y clock signal CLY and the inverted Y clock signal CLYinv.

Further, the data line driving circuit 101 includes X-side shift register 101a and arithmetic logic units 170 disposed correspondingly to each stage of the X-side shift register 101a. The X-side shift register 101a is supplied with the X clock signal CLX, the inverted X clock signal CLXinv, and the X start pulse DX. When the X start pulse DX is input to the X-side shift register 101a, the X-side shift register 101a sequentially generates and outputs transfer signals SR1, . . . , SRn in each stage at the timing based on the X clock signal CLX and the inverted X clock signal CLXinv.

Each of the arithmetic logic units 170 is supplied with the transfer signals SRi (i=1, 2, . . . , n). Further, each of the arithmetic logic units 170 is supplied with the selection signal for precharge NRG and any one of the first and second enable signals ENB1 and ENB2. More specifically, the arithmetic logic units 170 corresponding to odd stages of the X-side shift register 101a are supplied with the first enable signal ENB1, and the arithmetic logic units 170 corresponding to even stages of the X-side shift register 101a are supplied with the second enable signal ENB2. Output signals SHg1, SHg2, . . . , SHgn are output to sampling switches 202 of the sampling circuit 200 from each of the operational units 170. Further, the detailed construction of each arithmetic logic unit 170 will be described below.

The sampling circuit 200 includes a plurality of sampling switches 202 composed of a single channel type TFT of P channel type or N channel type TFT. Furthermore, each of the sampling switches 202 may be composed of a complementary TFT.

The liquid crystal panel 100 further includes the data lines 114 and the scanning lines 112, each of which is wired lengthwise and crosswise, in the image display region 10a occupying the center of the TFT array substrate. The liquid crystal panel 100 further includes TFT 116 for switching-controlling pixel electrodes 9a of liquid crystal element 118 disposed in the shape of matrix, at each of pixel portions 70 corresponding to the intersections of the data lines 114 and the scanning lines 112. Further, in the present embodiment, the total number of the scanning lines 112 is m (here, m is a natural number equal to or greater than 2), and the total number of the data lines 114 is n (here, n is a natural number equal to or greater than 2).

The image signals VID1 to VID6 serial-parallel developed into 6 phases are supplied to the liquid crystal panel 100 via the image signal lines 171, respectively. Further, as shown in FIG. 4, the sampling circuit 200 is provided with arithmetic logic units 170 as one group of N sampling switches (in the present embodiment, 6 sampling switches) and correspondingly to the sampling switches 202 belonging to the one group. The sampling switches 202 belonging to the one group is supplied with the selection signal for precharge NRG and the sampling signal Si as output signal SHgi of the arithmetic logic units 170, respectively. The sampling switches 202 belonging to the one group samples the image signals VID1 to VID6 serial-parallel developed into 6 phases according to the selection signal for precharge NRG and the sampling signal Si and supplies to the N data lines (in the present embodiment, six data lines) 114 belonging to one group. Specifically, the data lines 114 belonging to the one group and the 6 image signal lines 171 are connected to each other via the sampling switches 202 belonging to the one group. Therefore, in the present embodiment, since the n data lines 114 are driven for every data line belonging to the one group, it is possible to control the driving frequency.

In FIG. 4, when it is focused on the construction of one pixel portion 70, the data line 114 to which the image signal VIDk (here, k=1, 2, 3, . . . , 6) is supplied is electrically connected to a source electrode of the TFT 116, the scanning line 112 to which the scanning signal Yj (here, j=1, 2, 3, . . . , m) is supplied is electrically connected to a gate electrode of the TFT 116, and the image electrode 9a of the liquid crystal element 118 is connected to a drain electrode of the TFT 116. Here, in each of the pixel portions 70, the liquid crystal element 118 has liquid crystal interposed between the pixel electrode 9a and the counter electrode 21. Therefore, each pixel region 70 is disposed in the shape of matrix correspondingly to each of the intersections of the scanning lines 112 and the data lines.

Each of the scanning lines 112 is, for example, sequentially selected according to the scanning signals Y1, . . . , Ym output from the scanning line driving circuit 104. In the pixel portion 70 corresponding to the selected scanning line 112, when the TFT 116 is supplied with the scanning signal Yj, the TFT 116 is turned on and the corresponding pixel portion 70 becomes into a selected state. The pixel electrode 9a of the liquid crystal element 118 is supplied with the image signal VIDk through the data line 114 at a predetermined timing, by turning off the switch for a predetermined period. In this way, an applying voltage regulated by each voltage of the pixel electrode 9a and the counter electrode 21 is applied to the liquid crystal element 118. The orientation or the order of molecular association of the liquid crystal is varied by the voltage level applied thereto, such that it is possible to perform a grayscale display by modulating light. In case of a normally white mode, the transmittance of an incident light is reduced in accordance with a voltage applied with a unit of each of the pixels, and in case of a normally black mode, the transmittance of an incident light is increased in accordance with a voltage applied with a unit of each of the pixels. On the whole, the light having the contrast according to the image signals VID1 to VID6 is emitted from the liquid crystal panel 100.

Here, a storage capacitor 119 is provided in parallel with the liquid crystal element 118 to prevent the retained image signal from being leaked. For example, since the voltage of the pixel electrode 9a is retained by the storage capacitor 119 for a time longer by three digits than the time in which the source voltage is applied, the retaining characteristic is improved, whereby it is possible to realize a high contrast ratio.

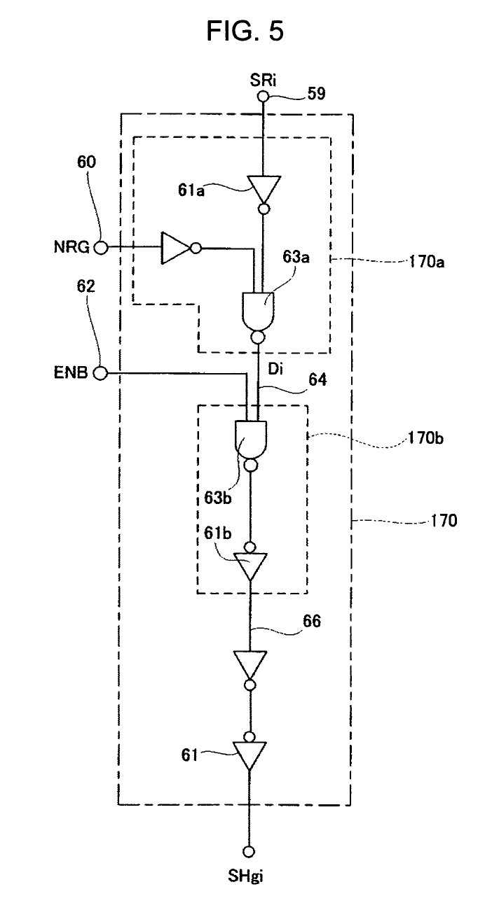

Here, the construction of the arithmetic logic unit 170 shown in FIG. 4 will be described with reference to FIG. 5. FIG. 5 is a circuit diagram showing the construction of the arithmetic logic unit 170. Further, the first or second enable signals ENB1 or ENB2 supplied to the any one of the arithmetic logic units 170 shown in FIG. 5 is shown as the enable signal ENB.

In FIG. 5, a first arithmetic logic circuit 170a and a second arithmetic logic circuit 170b are included as main parts of the arithmetic logic unit 170. The first arithmetic logic circuit 170a is supplied with the transfer signal SRi sequentially output from the X-side shift register 101a through an input terminal 59 thereof, and a first input terminal 60 is supplied with the selection signal for precharge NRG. In the first arithmetic logic circuit 170a, the supplied transfer signal SRi and the selection signal for precharge NRG are input to a NAND circuit 63a via inverters 61a, respectively. Then, the NAND circuit 63a outputs the transfer signal SRi and the selection signal for precharge NRG to the first path 64 as an output signal Di by the logical operation. Specifically, the arithmetic logic unit of the present embodiment is so constructed that the first arithmetic logic circuit 170a outputs the transfer signal SRi and the selection signal for precharge to the first path 64 by taking a logical sum of the transfer signal SRi and the selection signal for precharge.

Further, the second arithmetic logic circuit 170b includes, for example, a NAND circuit 63b and an inverter 61b. The NAND circuit 63b is supplied with the enable signal ENB through the second input terminal 62 disposed closer to the sampling circuit 200 compared to the first input terminal 60, and is supplied with the transfer signal SRi and the selection signal for precharge NRG as the output signal Di from the first path 64. The NAND circuit 63b generates the sampling signal Si by the logical operation between the transfer signal SRi and the enable signal ENB. Then, the selection signal for precharge NRG and the sampling signal Si as an output signal SHgi are output from the NAND circuit 63b to a second path 66 via the inverter 61b. Further, the output signal SHgi is output from the arithmetic logic unit 170 via two inverters 61 provided on the second path 66.

According to the above-described arithmetic logic unit 170, the number of logical operations using the enable signal ENB input to the second input terminal 62 is reduced compared to the number of logical operations until the selection signal for precharge NRG is output to the second path 66 after it is input to the second input terminal 60. Further, in the present embodiment, according to the arithmetic logic unit 170, it is possible to shorten the signal path until the sampling signal Si, which is the output signal SHgi, is output to the second path 66 after the enable signal ENB is input to the second input terminal 62, compared to the signal path until the selection signal for precharge NRG is output to the second path 66 after it is input to the input terminal 60.

<3: Operation of Electro-Optical Device>

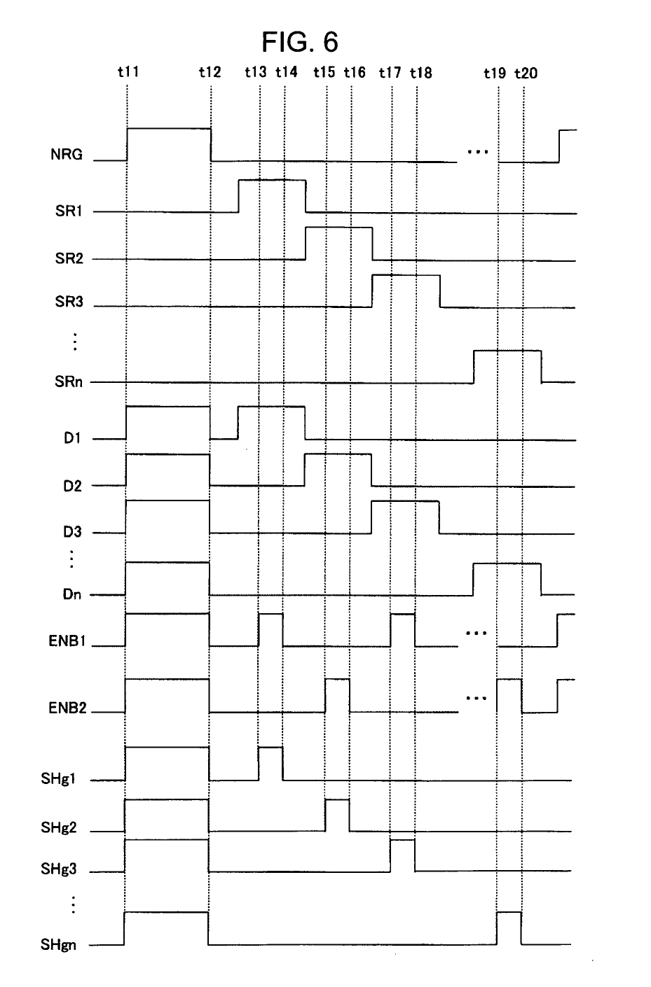

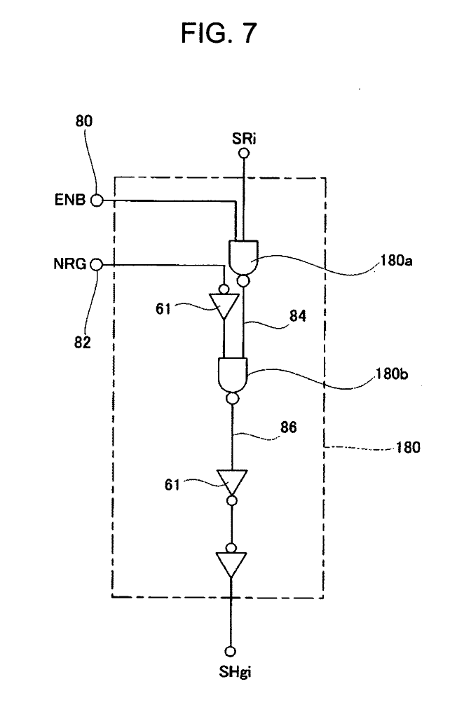

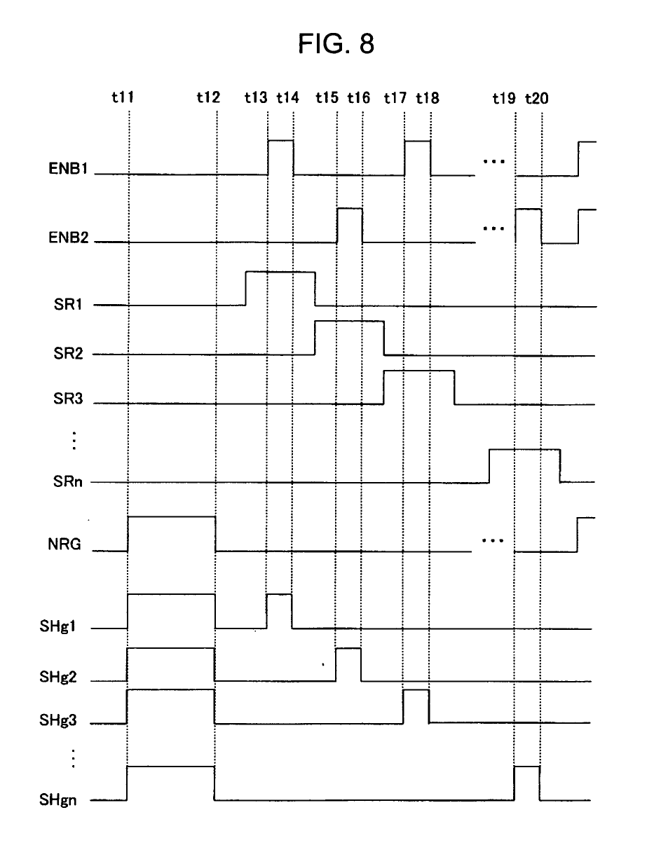

Next, the operation of the electro-optical device according to the present embodiment will be described with reference to FIGS. 6 to 8, in addition to FIGS. 1 to 5. FIG. 6 is a view showing a timing chart for illustrating the operation of an electro-optical device, FIG. 7 is a circuit diagram showing the construction of the arithmetic logic unit according to a comparative example, and FIG. 8 is a view showing the timing chart for illustrating the operation of the electro-optical device according to the comparative example.

During the time of operating the electro-optical device, the scanning signal Yj is supplied to each of the scanning lines 112 from the scanning line driving circuit 104 and the pixel portion 70 corresponding to each of the scanning line 112 is horizontally scanned. Hereinafter, the horizontal scanning, which is performed during one horizontal scanning period related to any one of the scanning lines 112, will be described.

In FIG. 6, when the scanning signal Yj is supplied from the scanning line driving circuit 104 to any one of the scanning lines 112 and one horizontal scanning period is started, during the period from time t11 to time t12, the selection signal for precharge NRG and the first and second enable signals ENB1 and ENB2 are supplied from the timing control circuit 400 so that the high level periods of the selection signal for precharge NRG and the first and second enable signals ENB1 and ENB2 are overlapped with each other on the time base, prior to the supply of X start pulse DX.

For each of the arithmetic logic units 170, the selection signal for precharge NRG input to the first input terminal 60 is inverted at the inverter 61a and is input to the NAND circuit 63a in the first arithmetic logic circuit 170a. At this time, since the transfer signal SRi is not input, the selection signal for precharge NRG is output as the output signal Di to the first path 64 from the NAND circuit 63a. Specifically, in each of the arithmetic logic units 170, the logical sum of the transfer signal SRi and the selection signal for precharge NRG is output to the first path 64.

In the second arithmetic logic circuit 170b, the NAND circuit 63b is supplied with the selection signal for precharge NRG, and the second input terminal 62 is supplied with the enable signal ENB. Then, the selection signal for precharge NRG is output to the second path 66 as the output signal SHgi via the inverter 61b from the NAND circuit 63b. Therefore, the plurality of sampling switches 202 of the sampling circuit 200 is supplied with the selection signal for precharge NRG at the same timing, and the plurality of sampling switches 202 is simultaneously turned on during the period from the time t11 to the time t12.

Further the image signal line 171 is supplied with the image signal VIDk having a predetermined precharge potential as the precharge signal in the invention from the image signal supply circuit 300, during the period from the time t11 to the time t12. Then, the image signal VIDk is supplied simultaneously to the plurality of data lines 114 wired in the image display region 10a via the plurality of sampling switches 202, and the pixel portions 70 corresponding to the scanning lines 112, to which the scanning signal Yj is supplied, are precharged during the period from the time t11 to the time t12. Specifically, the video precharge is performed during the period from the time t11 to the time t12.

After the video precharge is terminated at the time t12, the transfer signals SR1, SR2, SR3, . . . , SRn are sequentially output from the X-side shift register 101a. In the first arithmetic logic circuit 170a of each of the arithmetic logic units 170, the transfer signal SRi input to the input terminal 59 is inverted at the inverter 61a and is input to the NAND circuit 63a. At this time, since the supply of the selection signal NRG from the timing control circuit 400 is terminated, the transfer signal SRi is output as the output signal Di to the first path 64 from the NAND circuit 63a.

In each of the second arithmetic logic units 170b, the logical sum of the transfer signal SRi and the selection signal for precharge NRG and the logical sum with the enable signal ENB are output to the second path 66, from the NAND circuit 63b and the inverter 61b disposed at the post stage thereof, respectively.

Here, the first enable signal ENB1 and the second enable signal ENB2 are supplied alternately from the timing control circuit 400 so that, in synchronization with the output timing of the transfer signals SR1, SR2, SR3, . . . , SRn from the X-side shift register 101a, the first enable signal ENB1 is supplied to the second input terminal 62 of the arithmetic logic unit 170 corresponding to the odd stage of the X-side shift register 101a during the period from the time t13 to the time t14, the second enable signal ENB2 is supplied to the second input terminal 62 of the arithmetic logic unit 170 corresponding to the even stage of the X-side shift register 101a during the period from the time t15 to t16, and then the first enable signal ENB1 is supplied to the second input terminal 62 of the arithmetic logic unit 170 corresponding to the odd stage of the X-side shift register 101a during the period from the time t17 to the time t18. Therefore, during one horizontal scanning period, the first enable signal ENB1 is supplied with the number according to the transfer signal SRi output from the odd stage of the X-side shift register 101a and as the signal synchronized with the output timing of the transfer signal SRi, and the second enable signal ENB2 is supplied with the number according to the transfer signal SRi output from the even stage of the X-side shift register 101a and as the signal synchronized with the output timing of the transfer signal SRi. Therefore, as the number of the stages of the X-side shift register 101a increases, the first enable signal ENB1 and the second enable signal ENB2 are supplied as a high-speed pulse, respectively. In this way, the two series of enable signals ENB1 and ENB2 are supplied from the timing control circuit 400, such that it is possible to supply the first enable signal ENB1 and the second enable signal ENB2 as a low speed pulse, respectively, compared to the case in which only one series of enable signals are supplied from the timing control circuit 400.

Further, in the second arithmetic logic circuit 170b of each of the arithmetic logic units 170, the NAND circuit 63b is supplied with the enable signal ENB through the second input terminal 62, and is supplied with the transfer signal SRi as the output signal Di from the first path 64. The NAND circuit 63b generates the sampling signal Si as the output signal SHgi through the logical operation between the transfer signal SRi and the enable signal ENB. The output signal SHgi is sequentially output so that the output signal SHg1 is output during the period from the time t13 to the time t14, the output signal SHg2 is output during the period from the time t15 to the time t16, and the output signal SHg3 is output during the period from the time t17 to the time t18. Further, during the period of the time 19 to the time t20, the final transfer signal SRn is waveform-shaped by the second enable signal ENB2 in the arithmetic logic unit 170 corresponding to the final stage of the X-side shift register 101a, and the output signal SHgn is output therefrom.

Therefore, in the sampling circuit 200, every sampling switch 202 belonging to the one group is sequentially turned on according to the output signal SHgi. Further, after the time t12, the image signal VIDk is supplied from the image signal supply circuit 300 to the image signal line 171. The image signal VIDk is sequentially supplied to every data line 114 of one group from the image signal line 171 via the sampling switch 202 turned on. The image signal VIDk having the display potential is written to the pixel portions 70 corresponding to the scanning line 112 to which the scanning signal Yj is supplied, from the data line 114. Then, the supply of the scanning signal Yj is terminated and the one horizontal scanning period is terminated.

Hereinafter, the circuit-construction and the operation of the arithmetic logic unit 180 according to the comparative example will be described with reference to the FIGS. 7 and 8.

In the comparative example, the main part of the arithmetic logic unit 180 includes the first arithmetic logic circuit 180a and the second arithmetic logic circuit 180 which are constructed by the NAND circuit, respectively. The first arithmetic logic circuit 180a is supplied with the enable signal ENB via the first input terminal 80, in addition to the transfer signal SRi. The first arithmetic logic circuit 180a generates the sampling signal Si through the logical operation between the transfer signal SRi and the enable signal NRG and outputs it to the first path 84.

Further, the second arithmetic logic circuit 180b is supplied with the sampling signal Si from the first path 64, and the selection signal for precharge NRG via the second input terminal 82 disposed closer to the sampling circuit 200 compared to the first input terminal 80. The second arithmetic logic circuit 180b outputs the sampling signal Si and the selection signal for precharge NRG inverted at the inverter 61 as the output signal SHgi to the second path 86 through the logical operation. Further, the output signal SHgi is output from the arithmetic logic unit 180 via the two inverters 61 provided at the second path 86.

According to the comparative example, during the time of driving the electro-optical device, as shown in FIG. 8, the selection signal for precharge NRG is supplied from the timing control circuit 400 during one horizontal scanning period. The comparative example is different from the present embodiment in that the first and second enable signals ENB1 and ENB2, of which the high level periods are overlapped with that of the selection signal for precharge NRG on the time base, are not supplied from the timing control circuit 400.

In the comparative example, according to the arithmetic logic unit 180 shown in FIGS. 7 and 8, since the enable signal ENB is input to the first input terminal 80 disposed apart from the sampling circuit 200 compared to the second input terminal 82, when it is compared to the construction of the arithmetic logic unit 170 shown in FIG. 5, the number of logical operations based on the enable signal ENB is larger than the number of logical operations based on the selection signal for precharge NRG. Especially, since the logical operation is performed by the two kinds of NAND circuits 180a and 180b until the sampling signal Si is output to the second path 86 after the enable signal ENB is input to the first input terminal 80, there is a problem in that the delay of the output timing of the sampling signal Si with respect to the input timing of the enable signal ENB to the first input terminal 80 becomes relatively enlarged.

According to the driving circuit of the invention, as described above, in each of the arithmetic logic units 170, the number of logical operations which use the enable signal is reduced, and the signal path 66, until the sampling signal Si is output to the second path 66 after the enable signal ENB is input to the second input terminal 62, is shortened, such that it is possible to prevent the output timing of the sampling signal Si to the second path 66 from being delayed with respect to the input timing of the enable signal ENB to the second input terminal 62.

Therefore, in the sampling circuit 200, it is possible to enlarge the margin of the ghosting generation in the display image caused by the delay of the on and off of the sampling switch 202. Specifically, according to the present embodiment, it is possible to prevent the ghosting in the display image from being generated and to prevent display irregularity caused by the delay of the output timing of the sampling signal Si from being generated. Thus, according to the present embodiment, it is possible to realize the image display with high quality in the electro-optical device.

<4: Modification>

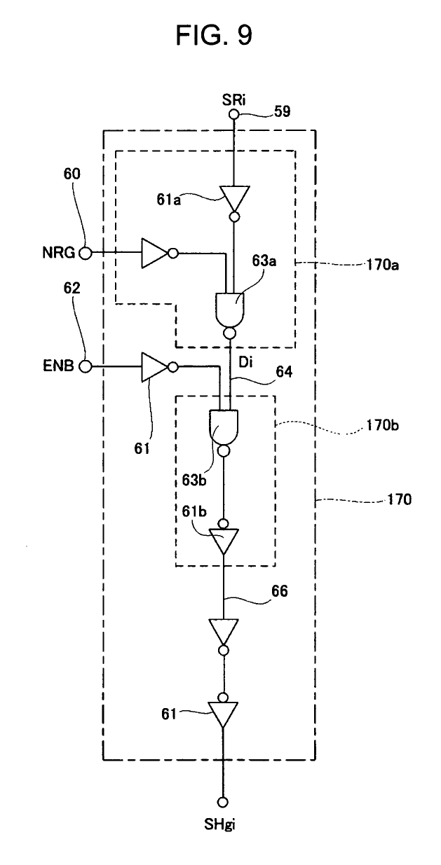

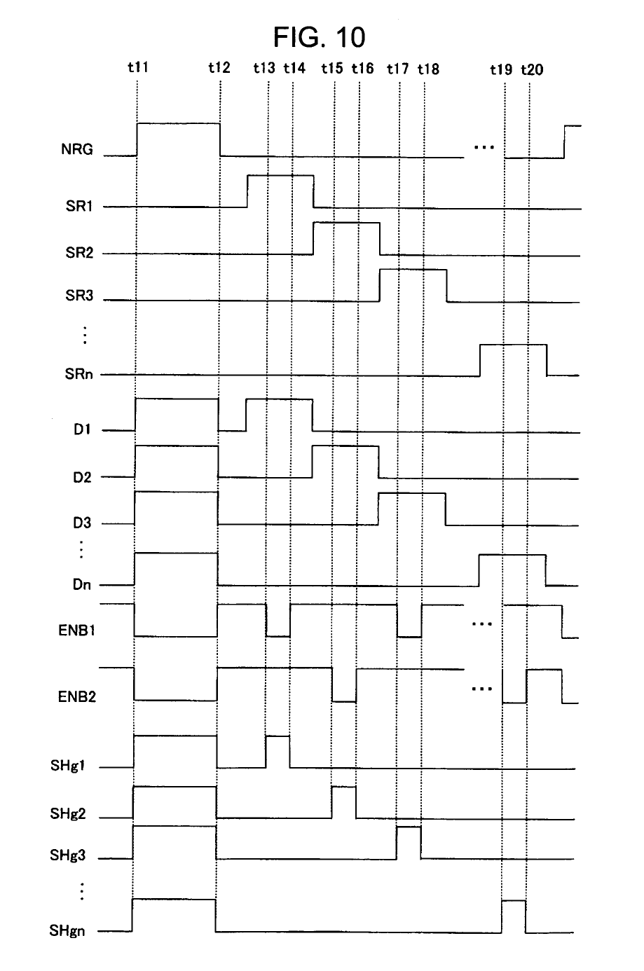

The modification of the present embodiment will be described with reference to FIGS. 9 and 10. FIG. 9 is a circuit diagram showing the arithmetic logic unit according to the present modification, and FIG. 10 is a view showing the timing chart for illustrating the operation of the electro-optical device according to the present modification.

In FIG. 9, the present modification is different from the construction shown in FIG. 5 in that the enable signal ENB input to the second input terminal 62 is input to the second arithmetic logic circuit 170b via the inverter 61.

During the time of operating the electro-optical device, as shown in FIG. 10, a signal, in which the logic of the first and second enable signals ENB1 and ENB2 shown in FIG. 6 is inverted, is supplied from the timing control circuit 400.

Therefore, with the arithmetic logic unit 170 as shown in FIG. 9, it is possible to obtain the same advantages as the present embodiment.

<5: Electronic Apparatus>

Hereinafter, the case in which the above-described liquid crystal device is applied to various electronic apparatus will be described.

<5-1: Projector>

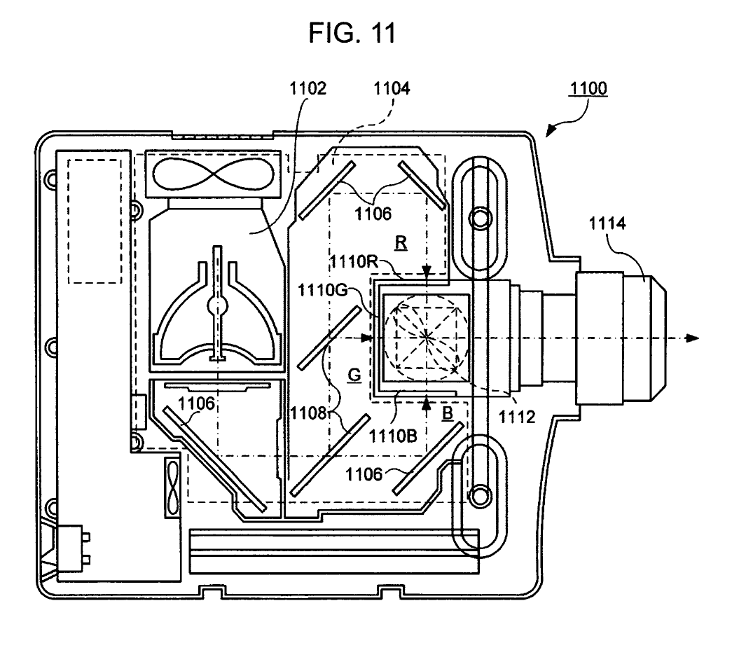

First a projector, which uses the present liquid crystal device as a light valve, will be described. FIG. 11 is a plan arrangement view showing a constructional example of the projector. As shown in FIG. 11, a lamp unit 1102 composed of a white light source such as a halogen lamp and the like is provided inside the projector 1100. An incident light emitted from the lamp unit 1102 is separated into three primary colors of R, G, and B by four mirrors 1106 and two dichroic mirrors 1108 disposed inside a light guide 1104 and the three primary colors are incident to light valves 1110R, 1110G, and 1110B corresponding to each of the primary colors. Each of the three light valves 1110R, 1110G, and 1110B is constituted by using a liquid crystal module including the liquid crystal device.

In the light valves 1110R, 1110G, and 1110B, the liquid crystal panel 100 is driven by primary color signals of R, G, and B supplied from the image signal supply circuit 300. The light modulated by such liquid panel 100 is incident into a dichroic prism 1112 from three directions. In the dichroic prism 1112, the light of R and B is refracted at an angle of 90° and the light of G goes straight. Therefore, an image of each color is synthesized, whereby a color image is projected onto a screen or the like through a projector lens 1114.

Here, when attention is focused on a display image by each of the light valves 1110R, 1110G, and 1110B, the display image by the light valve 1110G is needed to be mirror-inversed with respect to the display images by the light valves 1110R and 1110B.

Further, since light corresponding to each of the primary colors is incident to each of the light valves 1110R, 1110G, and 1110B by the dichroic mirrors 1108, there is no need to provide a color filter.

<5-2: Mobile Computer>

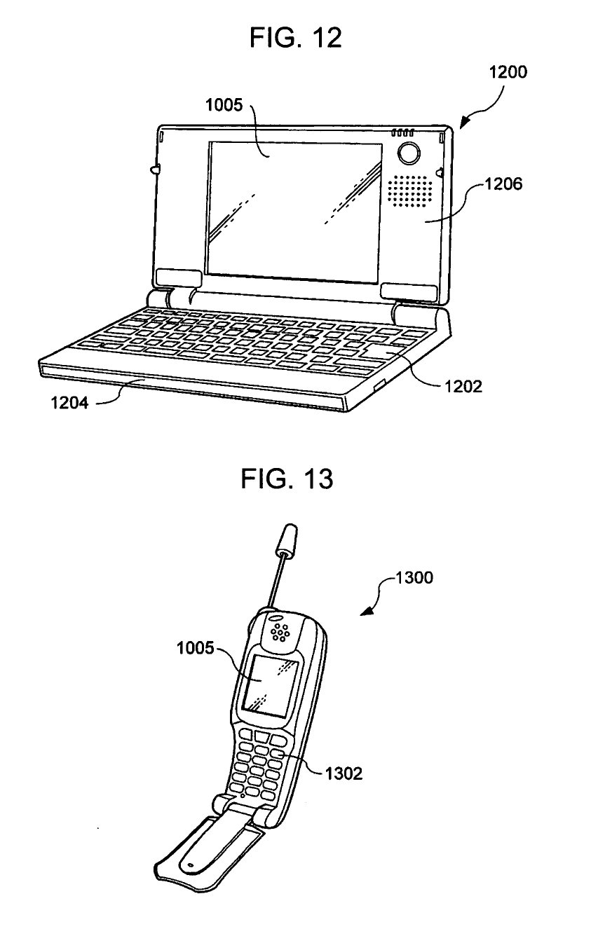

Hereinafter, an example in which the liquid crystal device is applied to a mobile personal computer will be described. FIG. 12 is a perspective view showing the construction of the personal computer. In the drawing, a computer 1200 is composed of a main body 1204 including a keyboard 1202, and a liquid crystal unit 1206. The liquid crystal unit 1206 is constituted by attaching a backlight to a rear surface of the above-described liquid crystal device.

<5-3: Mobile Telephone>

Further, an example in which the liquid crystal device is applied to a mobile telephone will be described. FIG. 13 is a perspective view showing the construction of the mobile telephone. In the drawing, the mobile telephone 1300 includes a plurality of operating buttons 1302 and a reflective liquid crystal device 1005. In the reflection type liquid crystal device 1005, a front light is provided on a front surface thereof, if needed.

Further, in addition to the electronic apparatus described with reference to FIGS. 1 to 13, a liquid crystal television, a view finder type or monitor-direct-view type video tape recorder, a car navigation device, a pager, an electronic organizer, an electronic calculator, a word processor, a workstation, a video telephone, a POS terminal, a device comprising a touch panel or the like can be exemplified. Further, it is needless to say that the liquid crystal device of the invention can be applied to the various electronic apparatus described above.

The invention is not limited to the above-described embodiment, and it is to be understood that changes and modifications may be made without departing from the spirit or scope of the invention as defined by the appended claims. The driving circuit and the driving method for driving electro-optical devices, the electro-optical device including the driving circuit, and the electronic apparatus including the electro-optical device according to the changes and modifications are also included in the scope of the invention.

What is claimed is:

1. A driving circuit of an electro-optical device having a plurality of scanning lines, a plurality of data lines, and a plurality of pixel electrodes electrically connected to the scanning lines and the data lines, respectively, in an image display region on a substrate, the driving circuit comprising:
a shift register circuit which sequentially outputs transfer signals from respective stages;
a first arithmetic logic circuit which outputs the sequentially output transfer signals and selection signals for precharge input from a first input terminal, to a first path by a logical operation;
a second arithmetic logic circuit which generates sampling signals by a logical operation between the transfer signals input from the first path and enable signals input from a second input terminal, and which outputs the generated sampling signals and the selection signals for precharge input from the first path to a second path; and
a sampling circuit including a plurality of sampling switches which sample precharge signals, which are supplied via an image signal line and have precharge potentials, according to the selection signals for precharge supplied via the second path, and supplies the sampled signals to the data lines, respectively, and sample image signals, which are supplied via the image signal line and have display potentials, according to the sampling signals supplied via the second path, and which supplies the sampled signals to the data lines, respectively.

2. The driving circuit of the electro-optical device according to claim 1,
wherein the first and second arithmetic logic circuits are constructed so that the number of logical operations operated from the second input terminal to the second path is smaller than the number of logical operations operated from the first input terminal to the second path.

3. The driving circuit of the electro-optical device according to claim 1,
wherein the second input terminal is disposed closer to the sampling circuit than the first input terminal.

4. The driving circuit of the electro-optical device according to claim 1,
wherein the first arithmetic logic circuit outputs the transfer signals and the selection signals for precharge to the first path by performing logical sums of the transfer signals and the selection signals for precharge, and
wherein the second arithmetic logic circuit generates the sampling signal by performing logical multiplications of the transfer signals and the enable signals.

5. The driving circuit of the electro-optical device according to claim 1,
wherein any one of the plural types of enable signals is supplied to the second input terminal.

6. An electro-optical device including the driving circuit of the electro-optical device according to claim 1.

7. An electronic apparatus including the electro-optical device according to claim 6.

8. A method of driving a driving circuit of an electro-optical device having a plurality of scanning lines, a plurality of data lines, and a plurality of pixel electrodes electrically connected to the scanning lines and the data lines, respectively, in an image display region on a substrate, the method comprising:
sequentially outputting transfer signals from respective stages;
outputting the sequentially output transfer signals and selection signals for precharge input from a first input terminal to a first path by a logical operation;
generating sampling signals by a logical operation between the transfer signals input from the first path and enable signals input from a second input terminal and outputting the generated sampling signals and the selection signals for precharge input from the first path to a second path; and
sampling precharge signals, which are supplied via an image signal line and have precharge potentials, according to the selection signals for precharge supplied via the second path and supplying the sampled signals to the data lines, respectively, and sampling image signals, which are supplied via the image signal line and have display potentials, according to the sampling signals supplied via the second path and supplying the sampled signals to the data lines, respectively.
